(19) United States
(12) Patent Application Publication
(10) Pub. No.: US 2024/0395555 A1
(43) Pub. Date: Nov. 28, 2024

(54) METHOD OF FORMING CHROMIUM NITRIDE LAYER AND STRUCTURE INCLUDING THE CHROMIUM NITRIDE LAYER

(71) Applicant: ASM IP Holding B.V., Almere (NL)

(72) Inventors: Qi Xie, Wilsele (BE); Eric James Shero, Phoenix, AZ (US); Charles Dezelah, Helsinki (FI); Giuseppe Alessio Verni, Ottignies (BE); Petri Raisanen, Gilbert, AZ (US)

(21) Appl. No.: 18/791,605

(22) Filed: Aug. 1, 2024

Related U.S. Application Data
(63) Continuation of application No. 17/227,621, filed on Apr. 12, 2021, now Pat. No. 12,087,586.
(60) Provisional application No. 63/014,038, filed on Apr. 22, 2020.
(60) Provisional application No. 63/010,560, filed on Apr. 15, 2020.

(51) Int. Cl. H01L 21/28; C23C 16/34; C23C 16/455; C23C 16/52; H01L 29/49

(52) U.S. Cl. CPC H01L 21/28088; C23C 16/34; C23C 16/45544; C23C 16/52; H01L 29/4966

(57) ABSTRACT

Methods and systems for depositing chromium nitride layers onto a surface of the substrate and structures and devices formed using the methods are disclosed. An exemplary method includes using a deposition process, depositing a chromium nitride layer onto a surface of the substrate. The deposition process can include providing a chromium precursor to the reaction chamber and separately providing a nitrogen reactant to the reaction chamber. The deposition process may be a thermal cyclical deposition process.

### CROSS-REFERENCE TO RELATED APPLICATIONS

This application is a continuation of, and claims priority to, U.S. patent application Ser. No. 17/227,621, filed Apr. 12, 2021 and titled METHOD OF FORMING CHROMIUM NITRIDE LAYER AND STRUCTURE INCLUDING THE CHROMIUM NITRIDE LAYER; which claims priority to U.S. Provisional Patent Application Ser. No. 63/014,038, filed on Apr. 22, 2020 and U.S. Provisional Patent Application Ser. No. 63/010,560, filed on Apr. 15, 2020, the disclosures of which are hereby incorporated by reference in their entirety.

### FIELD OF INVENTION

The present disclosure generally relates to methods and systems suitable for forming a layer on a surface of a substrate and to structures including the layer. More particularly, the disclosure relates to methods and systems for forming layers that include chromium nitride and to structures formed using the methods and systems.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

For example, one challenge has been finding a suitable conducting material for use as a gate electrode in the CMOS devices. CMOS devices have conventionally used n-type doped polysilicon as the gate electrode material. However, doped polysilicon may not be an ideal gate electrode material for advanced node applications. Although doped polysilicon is conductive, there may still be a surface region which can be depleted of carriers under bias conditions. This region may appear as an extra gate insulator thickness, commonly referred to as gate depletion, and may contribute to the equivalent oxide thickness. While the gate depletion region may be thin, on the order of a few angstroms (Å), the gate depletion region may become significant as the gate oxide thicknesses are reduced in advanced node applications. As a further example, polysilicon does not exhibit an ideal effective work function (eWF) for both NMOS and PMOS devices. To overcome the non-ideal effective work function of doped polysilicon, a threshold voltage adjustment implantation may be utilized. However, as device geometries reduce in advanced node applications, the threshold voltage adjustment implantation processes may become increasingly complex and impractical.

To overcome problems associated with doped polysilicon gate electrodes, polysilicon gate material may be replaced with an alternative material, such as, for example, a titanium nitride layer. The titanium nitride layer may provide a more ideal effective work function for CMOS applications. However, in some cases, where higher work function values than those obtained with titanium nitride layers—e.g., in PMOS regions of a CMOS device—are desired, improved materials for gate electrodes are desired. Such materials may also be suitable for other electrode/capacitor applications, such as dynamic random access memory (DRAM) applications, as well as other applications.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming structures including chromium nitride layers, to structures and devices formed using such methods, and to apparatus for performing the methods and/or for forming the structures and/or devices. While the ways in which various embodiments of the present disclosure address drawbacks of prior methods and systems are discussed in more detail below, in general, various embodiments of the disclosure provide improved methods of forming chromium nitride layers that exhibit relatively high work function values. Additionally or alternatively, chromium nitride layers can be formed using one or more chromium precursors. Further, exemplary chromium nitride layers can be formed using a thermal cyclical deposition process—without using a plasma or plasma-activated species. Alternatively, a process using plasma or plasma-activated species can be utilized. If such a process is used, the plasma may be N₂ plasma, N₂/H₂ plasma or NH₃ plasma.

In accordance with exemplary embodiments of the disclosure, a method of forming a gate electrode structure is disclosed. Exemplary methods of forming the gate electrode structure include providing a substrate within a reaction chamber of a reactor and, using a deposition process, depositing a chromium nitride layer onto a surface of the substrate. The deposition process can include (e.g., sequentially and separately) providing a chromium precursor to the reaction chamber and providing a nitrogen reactant to the reaction chamber. The chromium precursor can include one or more of a chromium amidinate precursor, chromium amido precursor, chromium diazadiene precursor, chromium cyclopentadienyl precursor, chromium zero valent precursor, chromium oxyhalide precursor, chromium beta-diketonate precursor, chromium aminoalkoxide precursor, chromium iminoalkoxide precursor, chromium alkoxyalkoxide precursor and a heteroleptic chromium precursor. The chromium can be selected from the group consisting of chromium fluoride, chromium chloride, chromium bromide, chromium iodide, and the like. The chromium oxyhalide can be selected from the group consisting of a chromium oxyfluoride, a chromium oxychloride, a chromium oxybromide, a chromium oxyiodide, and the like. The nitrogen reactant can be selected from one or more of ammonia (NH₃), hydrazine (N₂H₄), other nitrogen and hydrogen-containing gases, and the like. The deposition process may be cyclical. The cyclical deposition process can include one or more of an atomic layer deposition process and a cyclical chemical vapor deposition process. The cyclical deposition process can include a thermal process—i.e., a process that does not use plasma-activated species. Use of a thermal process may be desirable for some applications, such as formation of gate structures, because use of plasma for such applications may be detrimental to device performance.

In accordance with further exemplary embodiments of the disclosure, a method of forming a structure comprising a chromium nitride layer includes providing a substrate within a reaction chamber of a reactor and, using a thermal cyclical deposition process, depositing a layer comprising chromium nitride onto a surface of the substrate. The thermal cyclical deposition process can include providing a chromium precursor to the reaction chamber and providing a nitrogen reactant to the reaction chamber. The chromium precursor and the nitrogen reactant can be the same or similar to the chromium precursor and the nitrogen reactant described above and elsewhere herein. In accordance with examples of the disclosure, the thermal cyclical deposition process does not include use of a nitrogen plasma, does not include use of excited nitrogen species, does not include use of nitrogen radicals, and/or does not include use of diatomic nitrogen as a nitrogen reactant.

In accordance with yet further exemplary embodiments of the disclosure, a structure is formed using a method as described herein. The structure can include a substrate and a chromium nitride layer formed overlying a surface of the substrate. Exemplary structures can further include one or more additional layers, such as an additional metal or conducting layer overlying the chromium nitride layer. The structure can be or form part of a CMOS structure, such as one or more of a PMOS and NMOS structure.

In accordance with yet additional embodiments of the disclosure, a device or portion thereof can be formed using a method and/or a structure as described herein. The device can include a substrate, an insulating or dielectric layer, a chromium nitride layer overlying the insulating or dielectric layer, and optionally an additional metal layer overlying the chromium nitride layer. The device can be or form part of a CMOS device.

In accordance with yet additional examples of the disclosure, a system to perform a method as described herein and/or to form a structure, device, or portion of either, is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a structure/device portion in accordance with exemplary embodiments of the disclosure.

FIG. 3 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures, such as gate electrode structures. Exemplary methods can be used to, for example, form CMOS devices or portions thereof. The method according to the current disclosure may be used to produce a structure comprising the chromium nitride layer and a device comprising the chromium nitride layer. The chromium nitride layer according to the current disclosure may be used as work function metal in metal gates, liner/barrier, metal electrode (DRAM, Logic, 3DNAND) and also p-metal gate for logic and also as a dipole (p) tuning layer for logic and other applications. However, unless noted otherwise, the invention is not necessarily limited to such examples.

Further, exemplary methods can include forming a chromium nitride layer using a cyclical deposition process. In accordance with examples of the disclosure, a (e.g., thermal) cyclical deposition process includes providing a chromium precursor to the reaction chamber and providing a nitrogen reactant to the reaction chamber. In accordance with these examples, no activated species, such as radicals, ions, or the like, are formed using a plasma.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include He and Ar and any combination thereof. In some cases, nitrogen and/or hydrogen can be an inert gas. Gas used for purging, i.e. a purge gas, may be an inert gas.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying the substrate, such as one or more layers formed according to a method as described herein.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, a “chromium nitride layer” can be a material layer that can be represented by a chemical formula that includes chromium and nitrogen. A chromium nitride layer can include additional elements, such as oxygen (e.g., a chromium oxynitride layer), carbon (chromium carbonitride), and the like. In other words, the chromium nitride layer may comprise CrₓN_{y}C_{z} or CrₓN_{y}O_{z}.

As used herein, a “chromium precursor” includes a gas or a material that can become gaseous and that can be represented by a chemical formula that includes chromium.

The term “nitrogen reactant” can refer to a gas or a material that can become gaseous and that can be represented by a chemical formula that includes nitrogen. In some cases, the chemical formula includes nitrogen and hydrogen. In some cases, the nitrogen reactant does not include diatomic nitrogen. Examples of nitrogen reactants include compounds of the general formula R₂NNR₂, where each R is independently one of the following: H, Me, Et, iPr, tBu, Ph, Bz, SiMe₃, Cy. Additionally, R may represent other alkyl, aryl or silyl substituents.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

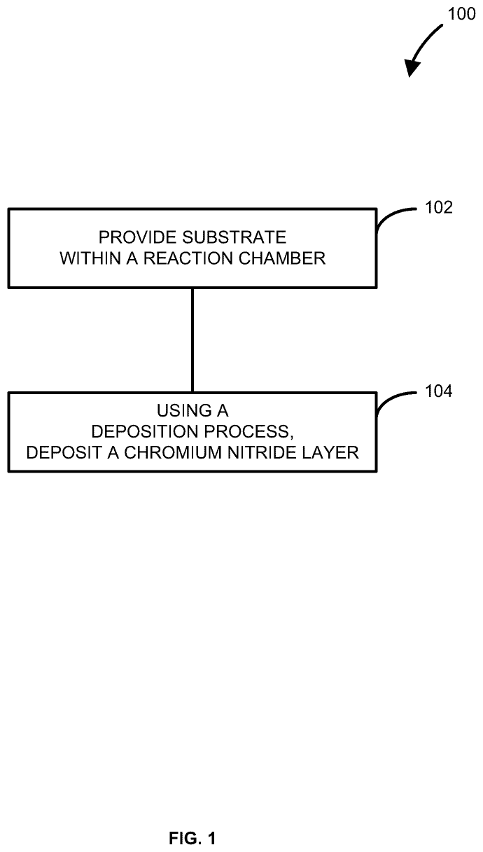

Turning now to the figures, FIG. 1 illustrates a method 100 in accordance with exemplary embodiments of the disclosure. Method 100 can be used to, for example, form a gate electrode structure suitable for NMOS, PMOS, and/or CMOS devices. However, unless otherwise noted, methods are not limited to such applications.

Method 100 includes the steps of providing a substrate within a reaction chamber of a reactor (step 102) and using a deposition process, depositing a layer comprising chromium nitride onto a surface of the substrate (step 104).

During step 102, a substrate is provided within a reaction chamber. The reaction chamber used during step 102 can be or include a reaction chamber of a chemical vapor deposition reactor system configured to perform a deposition process. The deposition process may be cyclical. In an embodiment, the deposition process is a cyclical deposition process. Further, in an embodiment, providing a chromium precursor to the reaction chamber and providing a nitrogen reactant to the reaction chamber are separated by a purge step. The embodiment comprising a purge step may be a cyclical deposition process. The reaction chamber can be a stand-alone reaction chamber or part of a cluster tool.

Step 102 can include heating the substrate to a desired deposition temperature within the reaction chamber. In some embodiments of the disclosure, step 102 includes heating the substrate to a temperature of less than 800° C. For example, in some embodiments of the disclosure, heating the substrate to a deposition temperature may comprise heating the substrate to a temperature between approximately 20° C. and approximately 800° C., or between approximately 100° C. and 600° C., or between approximately 200° C. and 500° C.

In addition to controlling the temperature of the substrate, a pressure within the reaction chamber may also be regulated. For example, in some embodiments of the disclosure, the pressure within the reaction chamber during step 102 may be less than 760 Torr or between 0.001 Torr and 760 Torr, or between 0.1 Torr and 760 Torr, or between 10 Torr and 760 Torr, or between 50 Torr and 760 Torr.

During step 104, a chromium nitride layer is deposited onto a surface of the substrate using a deposition process. As noted above, the deposition process can include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of reactants. Such a process may be referred to as cyclical CVD. In some embodiments, a cyclical CVD process may comprise the introduction of two or more reactants into the reaction chamber, wherein there may be a time period of overlap between the two or more reactants in the reaction chamber resulting in both an ALD component of the deposition and a CVD component of the deposition. This is referred to as a hybrid process. For example, a cyclical deposition process may comprise the continuous flow of one reactant and the periodic pulsing of a second reactant into the reaction chamber.

In accordance with examples of the disclosure, the cyclical deposition process may be a thermal deposition process. In these cases, the cyclical deposition process does not include use of a plasma to form activated species for use in the cyclical deposition process. For example, the cyclical deposition process may not comprise formation or use of a nitrogen plasma, may not comprise formation or use of excited nitrogen species, and/or may not comprise formation or use or nitrogen radicals. In an embodiment, the deposition process comprises the continuous flow of at least one precursor/reactant.

The cyclical deposition process can include (e.g., separately and/or sequentially) providing a chromium precursor to the reaction chamber and providing a nitrogen reactant to the reaction chamber. The chromium precursor can include one or more of a chromium amidinate precursor, a chromium amido precursor and a chromium diazadiene precursor.

The chromium amidinate precursors may be, for example, Cr(iPrFMD)ₓ, Cr(tBuFMD)ₓ, Cr(iPrAMD)ₓ or Cr(tBuAMD)ₓ, where x=2 or 3. As is common in the art, FMD stands for a formamidinate ligand, and AMD for an acetamidinate ligand. The chromium amido precursor may be, for example Cr[N(iPr)₂]₃, Cr[N(SiMe₃)₂]₃. Other similarly substituted variants can be envisaged. The chromium diazadiene precursor may be, for example, Cr(tBu₂DAD)₂, Cr(tBu₂DAD)₃, Cr(iPr₂DAD)₃ or Cr(iPr₂DAD)₃. Also other substituted DAD ligands can be envisaged.

The chromium precursor may include also one or more cyclopentadienyl precursors or zero valent precursors. Chromium cyclopentadienyl precursor may be, for example, CrCp₂, Cr(MeCp)₂, Cr(EtCp)₂, Cr(iPrCp)₂, Cr(tBuCp)₂, Cr(nBuCp)₂, Cr(Me₅Cp)₂ and Cr(Me₄Cp)₂. The chromium cyclopentadienyl precursor may also be another similarly substituted variant. Chromium zero valent precursor may be, for example, Cr(η⁶-benzene)(CO)₃, Cr(CO)₆, Cr(η⁶-benzene)₂, or other variant where the benzene ligand has one to six alkyl substituents.

The chromium precursor may be a chromium oxyhalide precursor. By way of examples, the chromium oxyhalide can be selected from one or more of chromium oxyhalides, such as one or more of a chromium oxyfluoride, a chromium oxychloride, a chromium oxybromide, and a chromium oxyiodide. The chromium oxyhalide can include only chromium, oxygen, and one or more halides. By way of example, the chromium oxyhalide can include chromium oxytrichloride or the like.

Further, chromium precursor may be an alkoxyalkoxide precursor of the formula Cr(R′R″COCH₂OR)ₓ, where R, R′, and R″ can independently be any alkyl or aryl group, including Me, Et, nPr, iPr, nBu, sBu, tBu, Cy, Ph, Bz, and where x=2 or 3. Chromium precursor may also be beta-diketonate precursor, such as Cr(acac)ₓ, Cr(thd)ₓ, Cr(hfac)ₓ, where x=2 or 3. As common in the art, acac stands for acetylacetonate, thd for 1,1,6,6-tetramethylheptandionate and hfac for hexaflouroacetylacetonate. Still further, chromium precursor may also be an aminoalkoxide precursor or an iminoalkoxide precursor, such as Cr(R′R″COCH₂NR₂)ₓ, Cr(R′R″COCHNR)ₓ, where each of R, R′, and R″ can independently be any alkyl or aryl group, including Me, Et, nPr, iPr, nBu, sBu, tBu, Cy, Ph, Bz, and where x=2 or 3.

Also heteroleptic chromium precursors, comprising a combination of two or more different precursor types described above, may be used. For example, two, three or four different precursor types can be used. Examples of heteroleptic chromium precursors are CrO₂(acac)₂, CrCp(tBu₂DAD), and Cr(EtCp)(iPrAMD)₂.

The nitrogen reactant can be or include one or more of ammonia (NH₃), hydrazine (N₂H₄), or the like. Examples of hydrazine reactants include compounds of the general formula R₂NNR₂, where each R is independently one of the following: H, Me, Et, iPr, tBu, Ph, Bz, SiMe₃, Cy. Additionally, R may represent other alkyl, aryl or silyl substituents. The nitrogen reactant can include or consist of nitrogen and hydrogen. In some cases, the nitrogen reactant does not include diatomic nitrogen. In the case of thermal cyclical deposition processes, a duration of the step of providing nitrogen reactant to the reaction chamber can be relatively long to allow the nitrogen reactant to react with the precursor or a derivative thereof. For example, the duration can be greater than or equal to 5 seconds or greater than or equal to 10 seconds or between about 5 and 10 seconds.

As part of step 104, the reaction chamber can be purged using a vacuum and/or an inert gas, to mitigate gas phase reactions between reactants and enable self-saturating surface reactions—e.g., in the case of ALD. Additionally or alternatively, the substrate may be moved to separately contact a first vapor phase reactant and a second vapor phase reactant. Surplus chemicals and reaction byproducts, if any, can be removed from the substrate surface or reaction chamber, such as by purging the reaction space or by moving the substrate, before the substrate is contacted with the next reactive chemical. The reaction chamber can be purged after the step of providing a chromium precursor to the reaction chamber and/or after the step of providing a nitrogen reactant to the reaction chamber.

In some embodiments of the disclosure, method 100 includes repeating a unit deposition cycle that includes (1) providing a chromium precursor to the reaction chamber and (2) providing a nitrogen reactant to the reaction chamber, with optional purge or move steps after step (1) and/or (2). The deposition cycle can be repeated one or more times, based on, for example, desired thickness of the chromium nitride layer. For example, if the thickness of the chromium nitride layer is less than desired for a particular application, then the step of providing a chromium precursor to the reaction chamber and providing a nitrogen reactant to the reaction chamber can be repeated one or more times. Once the chromium nitride layer has been deposited to a desired thickness, the substrate can be subjected to additional processes to form a device structure and/or device.

In some embodiments, a step coverage of the chromium nitride layer is equal to or greater than about 50%, or greater than about 80%, or greater than about 90%, or about 95%, or about 98%, or about 99% or greater, in/on structures having aspect ratios (height/width) of more than about 2, more than about 5, more than about 10, more than about 25, more than about 50, or even more than about 100.

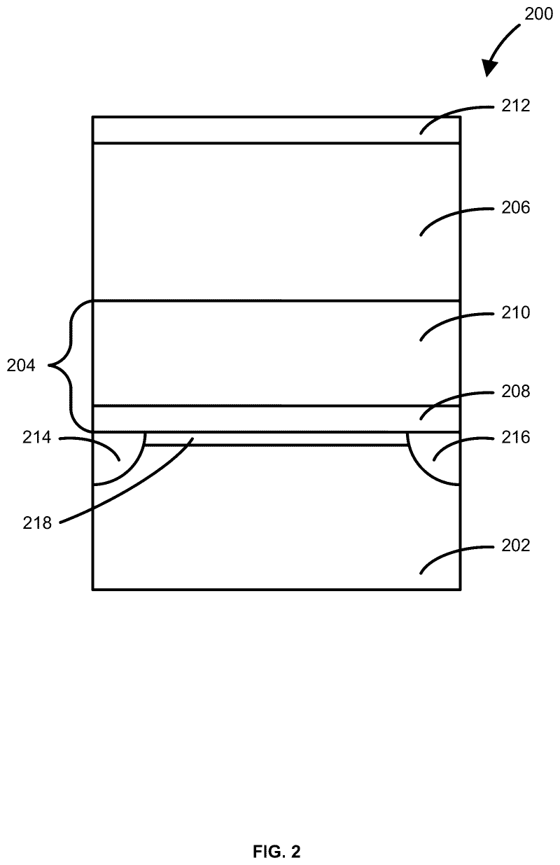

FIG. 2 illustrates a structure/a portion of a device 200 in accordance with additional examples of the disclosure. The portion of a device or structure 200 includes a substrate 202, dielectric or insulating material 204, and chromium nitride layer 206. In the illustrated example, structure 200 also includes an additional conducting layer 212.

Substrate 202 can be or include any of the substrate material described herein. In the illustrated example, substrate 202 includes a source region 214, a drain region 216, and a channel region 218. Although illustrated as a horizontal structure, structures and devices in accordance with examples of the disclosure can include vertical and/or three-dimensional structures and devices, such as FinFET devices, gate all around devices and nanosheet devices.

Dielectric or insulating material 204 can include one or more dielectric or insulating materials suitable for gate structure applications. By way of example, dielectric or insulating material 204 can include an interface layer 208 and a high-k material 210 deposited overlying interface layer 208. In some cases, interface layer 208 may not exist or may not exist to an appreciable extent. Interface layer 208 can include an oxide, such as a silicon oxide, which can be formed on a surface of the substrate 202 using, for example a chemical oxidation process or an oxide deposition process. High-k material 210 can be or include, for example, a metallic oxide having a dielectric constant greater than approximately 7. In some embodiments, the high-k material includes has a dielectric constant higher than the dielectric constant of silicon oxide. Exemplary high-k materials include one or more of hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃) or lanthanum oxide (La₂O₃), or mixtures/laminates thereof.

Chromium nitride layer 206 can be formed according to a method described herein. When chromium nitride layer 206 is formed using a cyclical deposition process, a concentration of chromium and/or nitrogen can vary from a bottom of chromium nitride layer 206 to a top of chromium nitride layer 206 by, for example, controlling an amount of chromium precursor and/or nitrogen reactant and/or respective pulse times during one or more deposition cycles. In some cases, chromium nitride layer 206 can have a stochiometric composition. A work function and other properties of chromium nitride layer 206 can be altered by altering an amount of nitrogen and/or chromium in the layer or in a deposition cycle.

Chromium nitride layer 206 can include oxygen. For example, chromium nitride layer 206 can be or include a chromium oxynitride layer. Chromium nitride layer 206 can include impurities, such as halides, hydrogen or the like in an amount of less than one atomic percent, less than 0.2 atomic percent, or less than about 0.1 atomic percent, or less than 0.05 atomic percent, alone or combined.

A work function of chromium nitride layer 206 can be >4.6 eV, >4.7 eV, >4.8 eV, >4.9 eV, >4.95 eV, or >5.0 eV. Additionally or alternatively, chromium nitride layer 206 can form a continuous film—e.g., using method 100—at a thickness of less than <5 nm, <4 nm, <3 nm, <2 nm, <1.5 nm, <1.2 nm, <1.0 nm, or <0.9 nm. Chromium nitride layer 206 can be relatively smooth, with relatively low grain boundary formation. In some cases, chromium nitride layer 206 may be amorphous, with relatively low columnar crystal structures (as compared to TiN). RMS roughness of exemplary chromium nitride layer 206 can be <1.0 nm, <0.7 nm, <0.5 nm, <0.4 nm, <0.35 nm, <0.3 nm, at a thickness of less than 10 nm.

Additional conducting layer 212 can include, for example, metal, such as a refractory metal or the like.

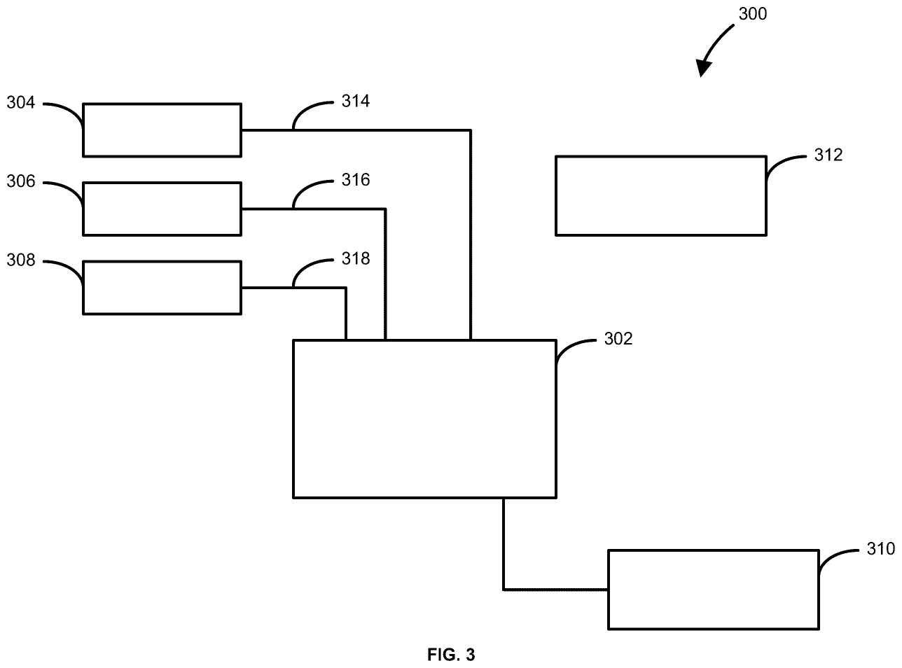

FIG. 3 illustrates a system 300 in accordance with yet additional exemplary embodiments of the disclosure. System 300 can be used to perform a method as described herein and/or form a structure or device portion as described herein.

In the illustrated example, system 300 includes one or more reaction chambers 302, a precursor gas source 304, a nitrogen reactant gas source 306, a purge gas source 308, an exhaust source 310, and a controller 312.

Reaction chamber 302 can include any suitable reaction chamber, such as an ALD or CVD reaction chamber.

Precursor gas source 304 can include a vessel and one or more chromium precursors as described herein—alone or mixed with one or more carrier (e.g., inert) gases. Nitrogen reactant gas source 306 can include a vessel and one or more nitrogen reactants as described herein—alone or mixed with one or more carrier gases. Purge gas source 308 can include one or more inert gases as described herein. Although illustrated with three gas sources 304-308, system 300 can include any suitable number of gas sources. Gas sources 304-308 can be coupled to reaction chamber 302 via lines 314-318, which can each include flow controllers, valves, heaters, and the like.

Exhaust source 310 can include one or more vacuum pumps.

Controller 312 includes electronic circuitry and software to selectively operate valves, manifolds, heaters, pumps and other components included in the system 300. Such circuitry and components operate to introduce precursors, reactants, and purge gases from the respective sources 304-308. Controller 312 can control timing of gas pulse sequences, temperature of the substrate and/or reaction chamber, pressure within the reaction chamber, and various other operations to provide proper operation of the system 300. Controller 312 can include control software to electrically or pneumatically control valves to control flow of precursors, reactants and purge gases into and out of the reaction chamber 302. Controller 312 can include modules such as a software or hardware component, e.g., a FPGA or ASIC, which performs certain tasks. A module can advantageously be configured to reside on the addressable storage medium of the control system and be configured to execute one or more processes.

Other configurations of system 300 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 302. Further, as a schematic representation of a system, many components have been omitted for simplicity of illustration, and such components may include, for example, various valves, manifolds, purifiers, heaters, containers, vents, and/or bypasses.

During operation of reactor system 300, substrates, such as semiconductor wafers (not illustrated), are transferred from, e.g., a substrate handling system to reaction chamber 302. Once substrate(s) are transferred to reaction chamber 302, one or more gases from gas sources 304-308, such as precursors, reactants, carrier gases, and/or purge gases, are introduced into reaction chamber 302.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a gate electrode structure, the method comprising the steps of:
providing a substrate within a reaction chamber of a reactor; and
depositing a chromium nitride layer onto a surface of the substrate,
wherein the deposition process comprises:
providing a chromium precursor to the reaction chamber; and
providing a nitrogen reactant to the reaction chamber, and
wherein the chromium precursor comprises one or more of a chromium zero valent precursor, a chromium oxyhalide precursor, a chromium beta-diketonate precursor, a chromium aminoalkoxide precursor, a chromium iminoalkoxide precursor, a chromium alkoxyalkoxide precursor, or a heteroleptic chromium precursor.

2. The method of claim 1, wherein the chromium precursor comprises the chromium oxyhalide selected from the group consisting of a chromium oxyfluoride, a chromium oxychloride, a chromium oxybromide, a chromium oxyiodide.

3. The method of claim 1, wherein the chromium precursor comprises the chromium zero valent precursor.

4. The method of claim 3, wherein the chromium zero valent precursor comprises Cr(η⁶-benzene)(CO)₃, Cr(CO)₆, Cr(η⁶-benzene)₂, or other variant where the benzene ligand has one to six alkyl substituents.

5. The method of claim 1, wherein the chromium precursor comprises the chromium beta-diketonate precursor.

6. The method of claim 5, wherein the chromium beta-diketonate precursor comprises one or more of Cr(acac)x, Cr(thd)x, Cr(hfac)x, where x=2 or 3.

7. The method of claim 1, wherein the chromium precursor comprises the chromium aminoalkoxide precursor or the iminoalkoxide precursor.

8. The method of claim 7, wherein the chromium precursor comprises one or more of Cr(R′R″COCH₂NR₂)ₓ, Cr(R′R″COCHNR)ₓ, where each of R, R′, and R″ can independently be any alkyl or aryl group, including Me, Et, nPr, iPr, nBu, sBu, tBu, Cy, Ph, Bz, and where x=2 or 3.

9. The method of claim 1, wherein the chromium precursor comprises the alkoxyalkoxide precursor.

10. The method of claim 1, wherein the chromium precursor comprises the heteroleptic chromium precursor.

11. The method of claim 1, wherein the deposition process is a cyclical deposition process.

12. The method of claim 11, wherein the cyclical deposition process comprises a cyclical chemical vapor deposition process.

13. The method of claim 11, wherein the cyclical deposition process comprises a thermal process.

14. The method of claim 1, wherein the nitrogen reactant is selected from one or more of ammonia (NH₃), hydrazine (N₂H₄), and other compounds comprising or consisting of nitrogen and hydrogen.

15. The method of claim 1, wherein the nitrogen reactant does not include diatomic nitrogen.

16. A method of forming a structure comprising a chromium nitride layer, the method comprising the steps of:
providing a substrate within a reaction chamber of a reactor; and
using a thermal deposition process, depositing a layer comprising chromium nitride onto a surface of the substrate,
wherein the thermal deposition process comprises:
providing a chromium precursor to the reaction chamber; and
providing a nitrogen reactant to the reaction chamber,
wherein the chromium precursor comprises one or more of a chromium zero valent precursor, a chromium oxyhalide precursor, a chromium beta-diketonate precursor, a chromium aminoalkoxide precursor, a chromium iminoalkoxide precursor, a chromium alkoxyalkoxide precursor, or a heteroleptic chromium precursor.

17. The method of claim 16, wherein the nitrogen reactant is selected from one or more of ammonia (NH₃), hydrazine (N₂H₄), and other compounds comprising or consisting of nitrogen and hydrogen.

18. A structure comprising a chromium nitride layer formed according to the method of claim 1.

19. A system comprising:
one or more reaction chambers;
a precursor gas source comprising a chromium precursor;
a nitrogen reactant gas source;
an exhaust source; and
a controller,
wherein the controller is configured to control gas flow into at least one of the one or more reaction chambers to perform the method of claim 16.

20. The system of claim 19, wherein the precursor gas source comprises one or more of the chromium zero valent precursor, the chromium oxyhalide precursor, the chromium beta-diketonate precursor, the chromium aminoalkoxide precursor, the chromium iminoalkoxide precursor, the chromium alkoxyalkoxide precursor, or the heteroleptic chromium precursor.
